(19) United States
(12) Patent Application Publication
(10) Pub. No.: US 2009/0080135 A1
(43) Pub. Date: Mar. 26, 2009

(54) Apparatus and Method for ESD Protection of an Integrated Circuit

(75) Inventor: Donald Edward MAJOR, Irvine, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 12/177,622

(22) Filed: Jul. 22, 2008

Related U.S. Application Data
(60) Provisional application No. 60/960,244, filed on Sep. 21, 2007.

(51) Int. Cl. H01H 47/00; H05K 3/00

(52) U.S. Cl. 361/220; 29/829

(57) ABSTRACT

Methods and apparatus for substrates with electrostatic discharge (ESD) protection are described. A substrate includes first and second ground planes and a trace that couples the first ground plane to the second ground plane. A signal passed by the first ground plane resulting from an electrostatic discharge (ESD) event interacts with a signal passed by the second ground plane resulting from the ESD event. The first and second ground planes are substantially isolated from each other when the first and second ground planes are coupled to a ground plane of a printed circuit board (PCB).

### CROSS REFERENCE TO RELATED APPLICATIONS

This application claims the benefit of U.S. Provisional Appl. No. 60/960,244, filed Sep. 21, 2007, which is incorporated by reference herein in its entirety.

### BACKGROUND OF THE INVENTION

1. Field of the Invention

The invention relates generally to the field of integrated circuit (IC) device packaging technology, and more particularly to improved substrates in IC device packages.

2. Background

Integrated circuits (ICs) include silicon chip circuitry and a package. The package includes traces and planes, dielectric layers, and pins or balls to connect to the IC to a printed circuit board or flex assembly used in the final application. Integrated circuit (IC) packages are often designed so that different circuit blocks remain isolated. For example, an IC package can be designed to isolate digital and analog components from each other in order to prevent the digital components from interfering with the analog components, and vice versa. Before mounting ICs onto a printed circuit board (PCB), they may be handled in various situations. For example, a person may move the IC from one location to another. Furthermore, a mechanical device may be used to mount the IC onto the PCB. When the IC package is being handled, it is vulnerable to electrostatic discharge (ESD) events that can severely damage or destroy the IC.

To protect the IC from ESD events, the various circuit blocks should be coupled to the same ground. This ensures that the ESD discharges have a path to ground with a low enough impedance so that a permanently damaging voltage level does not occur. Furthermore, most standardized ESD qualification tests allow only one ground to be connected on an IC being tested. However, by directly connecting the different circuit blocks to the same ground, isolation between the various circuit blocks can be reduced, which is undesirable.

Thus, what is needed is a method and system that provides ESD protection for IC while maintaining isolation between the various circuit blocks implemented therein.

### BRIEF SUMMARY

Apparatuses, methods, and systems for a substrate that provides electrostatic discharge (ESD) protection are described. A substrate includes first and second ground planes and a trace that couples the first ground plane to the second ground plane. A signal passed by the first ground plane resulting from an electrostatic discharge (ESD) event interacts with a signal passed by the second ground plane resulting from the ESD event. The first and second ground planes are substantially isolated when the first and second ground planes are coupled to a ground plane of a printed circuit board (PCB).

A method of forming a substrate includes providing first and second ground planes and electrically coupling the first and second ground planes. A signal passed by the first ground plane resulting from an electrostatic discharge (ESD) event interacts with a signal passed by the second ground plane resulting from the ESD event. The first and second ground planes are substantially isolated when the first and second ground planes are coupled to a ground plane of a printed circuit board (PCB).

These and other advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 illustrates an exemplary ball grid array (BGA) package.

FIGS. 2 and 3 illustrate exemplary substrates.

FIG. 4 illustrates an exemplary substrate, according to an embodiment of the present invention.

FIG. 5 illustrates an exemplary substrate mounted onto a printed circuit board, according to an embodiment of the present invention.

FIG. 6 illustrates an exemplary layer of a substrate, according to an embodiment of the present invention.

FIG. 7 shows a flowchart providing example steps for forming substrate, according to an embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

Overview

The present invention is directed to methods and apparatuses for integrated circuit (IC) packages with respect to ESD protection.

It is noted that references in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Example Integrated Circuit Packages

A ball grid array (BGA) package is used to package and interface an IC die with a circuit board such as a printed circuit board (PCB). BGA packages may be used with any type of IC die, and are particularly useful for high speed ICs. In a BGA package, solder pads do not utilize the surrounding of the package periphery, as in chip carrier type packages, but instead only cover the bottom package surface in an array configuration. BGA packages are also referred to as pad array carrier (PAC), pad array, land grid array, and pad-grid array packages. For additional description on BGA packages, refer to Lau, J. H., Ball Grid Array Technology, McGraw-Hill, New York, (1995), which is herein incorporated by reference in its entirety.

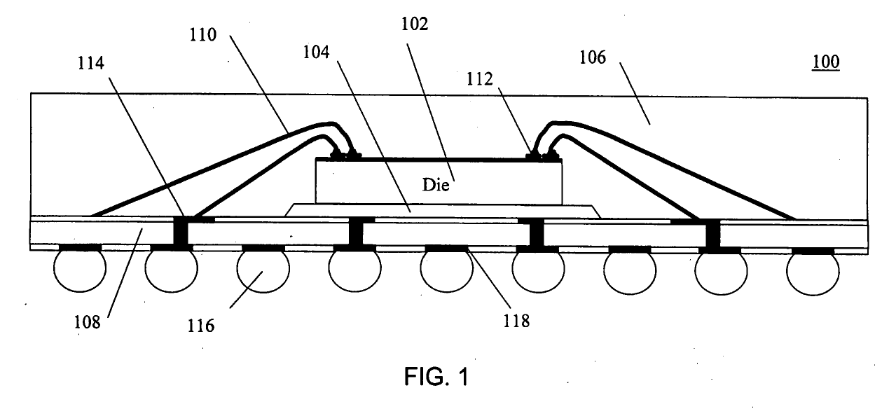

FIG. 1 shows an exemplary ball grid array (BGA) package 100. As shown in FIG. 1, BGA package 100 includes an IC die 102, an adhesive 104, a mold compound 106, a substrate 108, wirebonds 110, bond pads 112, bond fingers 114, solder balls 116, and contact pads 118. In the embodiment of FIG. 1, contact pads 118 are solder ball pads that allow solder balls 116 to be formed thereon. IC die 102 is attached to a first surface of substrate 108 using adhesive 104. Adhesive 104 may be a film, silver epoxy, or other thermally and/or electrically conductive adhesive. Wirebonds 110 couple bond pads 112 on a first surface IC die 102 to bond fingers 114 on the first surface of substrate 108. Wirebonds 110 may be formed out of an electrically conductive material such as gold or other metal. Bond fingers 114 electrically couple wirebonds 110 to contact pads 118 through substrate 108. Solder balls 116 are electrically coupled to contact pads 118 on a second surface of substrate 108. Solder balls 116 may be coupled to electrically conductive portions of a printed circuit board (PCB) to which package 100 is mounted. Mold compound 106 encapsulates IC die 102, wirebonds 110, and the first surface of substrate 108, for environmental protection.

Die-up and die-down BGA package configurations exist. In die-up BGA packages, the IC die is mounted on a top surface of the substrate, in a direction away from the PCB. In die-down BGA packages, the IC die is mounted on a bottom surface of the substrate, in a direction towards the PCB.

A number of BGA package substrate types exist, including ceramic, plastic, and tape (also known as “flex”). For example, substrate 108 may be a resin substrate.

In alternate embodiments, solder balls 116 may be replaced with other elements that may be coupled to electrically conductive portions of a PCB. For example, solder balls 116 may be replaced with pins to form a pin grid array package or solder paste to form a land grid array package.

Example Embodiments

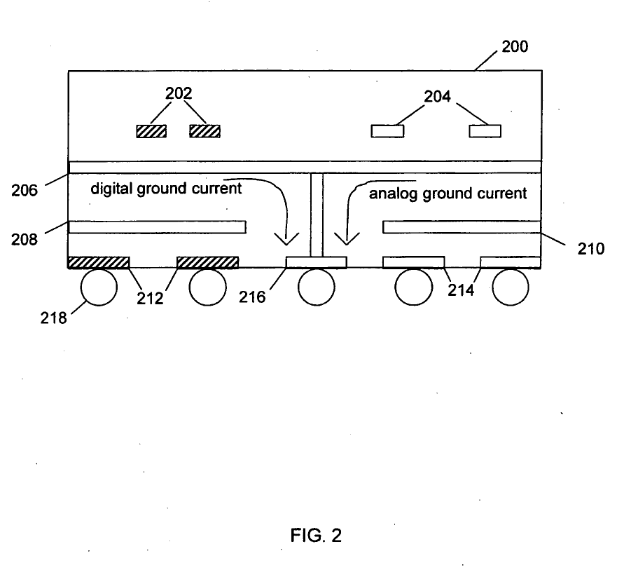

FIG. 2 shows a conventional substrate 200 that includes digital traces 202, analog traces 204, a ground plane 206, power planes 208 and 210, digital contact pads 212, analog contact pads 214, a ground contact pad 216, and solder balls 218. In an embodiment, substrate 200 may be coupled an IC die (not shown), e.g., similar to IC die 102, as described with reference to FIG. 1.

In an embodiment, solder balls 218 may be substantially similar to solder balls 116 described with reference to FIG. 1. Solder balls 218 can be used to couple contact pads 212, 214, and 216 to the PCB. In alternate embodiments, solder balls 218 can be replaced with pins or solder paste to form a pin grid array package or a land grid array package, respectively, as described above with reference to FIG. 1. In a further embodiment, contact pads 212, 214, and/or 216 can be adjusted to accept solder balls, pins, or paste depending on which type of package substrate 200 is to be included in.

Power planes 208 and 210 may be held at a constant voltage and may be used as power sources for one or more circuits implemented on the IC die.

Digital and analog traces 202 and 204 may be coupled to digital and analog circuits blocks, respectively. For example, one or more of digital traces 202 may be coupled to an output driver or a memory implemented in the IC die. In another example, one or more of analog traces 204 may be coupled to an analog signal processing circuit implemented in the IC die. FIG. 2 shows two digital traces 202 and two analog traces 204. However, as would be apparent to those skilled in the relevant art(s) based on the description herein, substrate may include any number of digital traces 202 and analog traces 204.

Digital and analog traces 202 and 204 can used to transmit a signal from a portion of substrate 200 to another portion of substrate 200. In an embodiment, signals transmitted using digital and analog traces 202 and 204 are voltage signals referenced to ground plane 206.

As described above, substrate 200 may be coupled an IC die. Bond fingers of substrate 200 (not shown) may be coupled to bond pads of the IC die through wirebonds. The bond fingers are routed through substrate 200, using traces, e.g., digital and analog traces 202 and 204, and vias, to contact pads of substrate 200. The contact pads of substrate 200 can be used to couple the bond pads to conductive portions of a PCB through solder balls 218.

In an embodiment, bond pads of the IC die may be coupled to a digital circuit block and other bond pads may be coupled to an analog circuit block. The digital bond pads on the IC die can be coupled to a PCB through bond fingers on substrate 200 that are coupled to digital contact pads 212. Similarly, the analog bond pads can be coupled to the PCB through bond fingers on substrate 200 that are coupled to analog contact pads 214. Ground plane 206 may be coupled to a ground plane of the PCB through ground contact pad 216.

It may be desired that the digital and analog circuit blocks of the IC die remain isolated. For example, analog circuits, such as signal processing circuits and reference sources, are typically sensitive to noise and other interference. Furthermore, digital circuits such as output drivers and memory can operate with high currents and produce substantial noise. Thus, digital circuits coupled to digital traces 202 may adversely affect the operation of analog circuits coupled to analog traces 204. Analog circuits coupled to analog traces 204 may also generate noise that adversely affects digital circuits coupled to digital traces 202. Analog circuits that are intended to be separate from each other may couple to each other, causing spurious responses or degraded performance.

Through the use of common ground plane 206, however, digital circuits coupled to digital traces 202 may interact with analog circuits coupled to analog traces 204 resulting in a performance degradation of one or both of the digital and analog circuits. Specifically, the use of ground plane 206 as a reference for digital and analog traces 202 and 204 can lead to unwanted interaction between ground currents of the digital and analog circuit blocks.

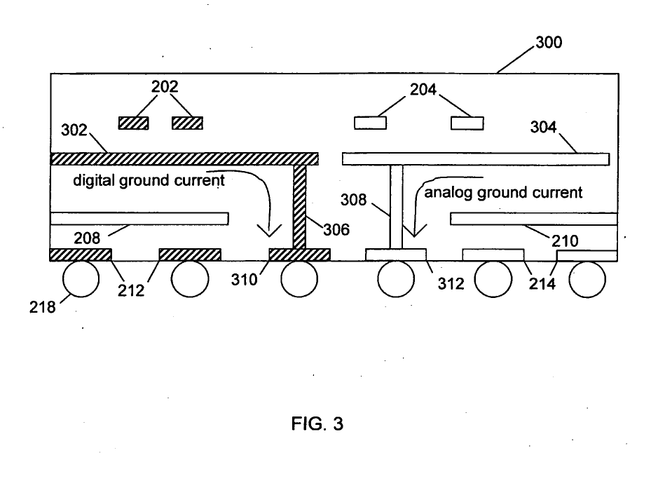

FIG. 3 shows another conventional substrate 300 that includes digital traces 202, analog traces 204, power planes 208 and 210, digital contact pads 212, analog contact pads 214, solder balls 218, a digital ground plane 302, an analog ground plane 304, vias 306 and 308, and contact pads 310 and 312.

In an embodiment, substrate 300 may provide additional isolation between digital and analog components as compared to substrate 200 shown in FIG. 2. Specifically, substrate 300 includes separate ground planes for each circuit block, e.g., digital ground plane 302 for the digital circuit block of the IC die and analog ground plane 304 for the analog circuit block of the IC die, so that interaction between digital and analog components is substantially decreased. Specifically, the separate ground planes help to ensure that digital and analog ground currents will not interact.

Although substrate 300 provides additional isolation by having separate ground planes for the digital and analog circuit blocks, substrate 300 can have drawbacks. For example, the IC package that includes substrate 300 may experience an electrostatic discharge (ESD) event as it is handled prior to being mounted to the PCB. As would be appreciated by those skilled in the relevant art(s), an IC package that allows for ground currents resulting from ESD events to flow through a sufficiently low impedance can be better suited to handle ESD events.

As described above, an IC package typically experiences an ESD event before it is mounted to a PCB. For example, an IC package may experience an ESD event when it is handled by a human being prior to mounting. Such an interaction may be modeled by a human body model (HBM). ESD events resulting from other interactions may also be modeled similarly. For example, an ESD event resulting from interaction with a machine, e.g., used to mount the IC package to the PCB, may be modeled with a machine model (MM) and interaction with a charged device that leads to an ESD event may be modeled with a charged device model (CDM), as would be appreciated by those skilled in the relevant art(s).

In embodiments described herein, a substrate package is provided that provides ESD protection by allowing ground currents resulting from ESD events from different ground planes to interact while still maintaining desired isolation between different circuit blocks when the substrate is mounted onto a PCB.

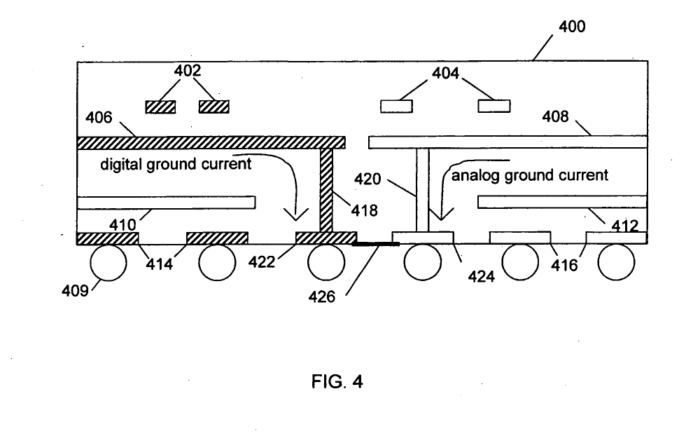

FIG. 4 shows a substrate 400, according to an embodiment of the present invention. Substrate 400 includes digital traces 402, analog traces 404, a digital ground plane 406, an analog ground plane 408, power planes 410 and 412, digital contact pads 414, analog contact pads 416, vias 418 and 420, contact pads 422 and 424, and a trace 426. In an embodiment, digital traces 402, analog traces 404, power planes 410 and 412, digital contact pads 414, analog contact pads 416, and solder balls 409 are generally similar to digital traces 202, analog traces 204, power planes 208 and 210, digital contact pads 212, analog contact pads 214, and solder balls 218, respectively, as described with reference to FIG. 2. Digital ground plane 406, analog ground plane 408, vias 418 and 420, and contact pads 422 and 424, can be generally similar to digital ground plane 302, analog ground plane 304, vias 306 and 308, and contact pads 310 and 312, respectively, as described with respect to FIG. 3.

Substrate 400 includes trace 426 that couples contact pad 422 to contact pad 424. Contact pads 422 and 424 are used to electrically couple ground planes 406 and 408, respectively, to a PCB. Specifically, contacts pads 422 and 424 couple to conductive elements (e.g., solder balls 409), which can be coupled to conductive portions of the PCB. Thus, contact pads 422 and 424 effectively allow ground planes 406 and 408, respectively, to communicate signals (e.g., ground signals) with a PCB.

Through trace 426, digital ground plane 406 is electrically coupled to analog ground plane 408. In an embodiment, trace 426 allows currents passed by digital and analog ground planes 406 and 408 resulting from an ESD event to interact over a sufficiently low impedance path such that ESD protection is provided.

In an embodiment, trace 426 is a circuit trace similar to other circuit traces of substrate 400. In FIG. 4, trace 426 is shown to be thin to indicate that it is relatively long and weak compared to digital and analog ground planes 406 and 408. For example, trace 426 may be generally similar to digital traces 402 and/or analog traces 404. In particular, trace 426 may be formed out of the same materials used to form the other traces of substrate 400, e.g., copper, and have similar dimensions as the other traces of substrate 400.

Although substrate 400 has been described with reference to the embodiment of FIG. 1, substrate 400 can also be incorporated with other types of ICs. For example, substrate 400 can be used in die down packages that include flip chip and/or wirebond connections.

Digital and analog ground planes 406 and 408 are described as being two separate ground planes. In an alternate embodiment, digital and analog ground planes 406 and 408 can instead be separate sections of the same ground plane. In such an embodiment, digital and analog ground plane sections 406 and 408 occupy the same layer plane, but are electrically isolated. More generally, two or more ground planes, as described herein, can refer to ground planes that occupy different layers of a substrate, ground plane sections that occupy the same layer of a substrate, or any combination thereof.

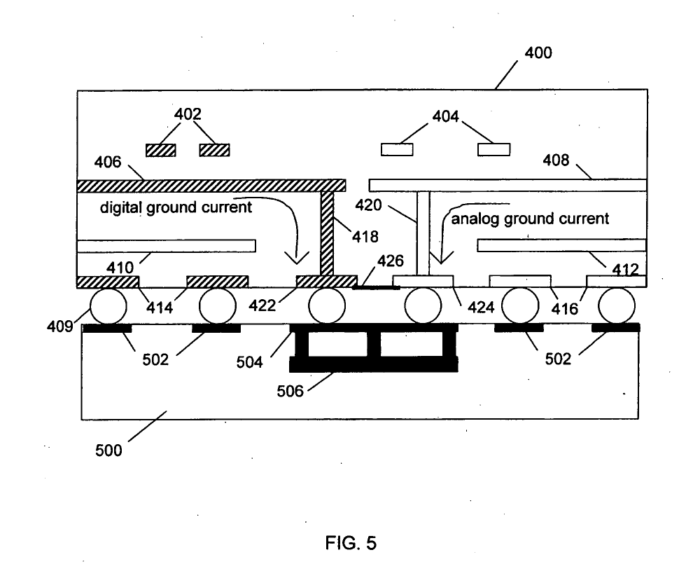

FIG. 5 shows substrate 400 coupled to a PCB 500, according to an embodiment of the present invention. PCB 500 includes contact pads 502 and ground contact pads 504. Ground contact pad 504 is coupled to a ground plane 506.

Through ground contact pads 504 and ground plane 506 each of contact pads 422 and 424 are strongly coupled to a ground potential making the voltage difference between contact pads 422 and 424 negligible. Since there is little or no voltage difference between contact pads 422 and 424, little or no current passes through trace 426 and interaction between the ground currents of digital ground plane 406 and analog ground plane 408 is prevented. Accordingly, noise generated in either of the digital circuit block coupled to digital ground plane 406 or the analog circuit block coupled to analog ground plane 408 does not affect the other circuit block once connected to the PCB.

In a further embodiment, trace 426 is made to be a weak connection to further prevent significant currents from passing across when substrate 400 is mounted to PCB 500. The connection between ground planes 406 and 408 is especially weak through trace 426 when compared to the connection between ground planes 406 and 408 and PCB ground plane 506. For example, as shown in FIG. 4, trace 426 is located relatively far away from digital and analog ground planes 406 and 408. In a further embodiment, trace 426 is located as far as possible away from digital and analog ground planes 406 and 408 while still remaining in substrate 400. By positioning trace 426 as far as possible away from digital and analog ground planes 406 and 408, the coupling between digital and analog ground planes 406 and 408 can be reduced. Thus, by keeping the voltage difference between contact pads 422 and 424 small and making trace 426 a relative weak connection, e.g., compared to the connection to ground provided by PCB ground plane 506, significant currents are prevented from passing over trace 426 and isolation between the digital and analog circuit blocks coupled to digital and analog ground planes 406 and 408 is maintained.

In another embodiment, the dimensions of trace 426 and/or material used to form trace 426 can be adjusted to further adjust the impedance of trace 426. For example, the impedance of trace 426 can be adjusted to ensure that it is low enough so that ESD protection is provided and high enough to ensure that significant currents do not pass over it after substrate 400 is mounted onto PCB 500, e.g., on the order of 10Ω (i.e., ohms), 1Ω, or 0.1Ω.

Furthermore, since trace 426 is included in substrate 400, e.g., in a packaging aspect of the IC package, its impact on the physical design of the IC die is minimized. Thus, the customization of the IC package required to include trace 426 can be done inexpensively and quickly.

In alternate embodiments, digital and analog ground planes 406 and 408 may be coupled in other ways. For example, vias 418 and 420, which are coupled to digital and analog ground planes 406 and 408, respectively, may be coupled through a trace substantially similar to trace 426 (not shown).

In embodiments described above, digital circuit blocks are separated from analog circuit blocks. In alternate embodiments, a circuit block may be separated from another similar circuit block. For example, an analog circuit block coupled to a first analog ground plane may be separated or isolated from another analog circuit block coupled to a second analog ground plane. When these circuit blocks are coupled in a manner as described above, e.g., by coupling respective contact pads using a trace similar to trace 426, ESD protection is obtained without compromising the isolation between the two circuit blocks when the IC package is coupled to a PCB. In a further embodiment, traces can be used to couple all of the different ground planes of an IC package to provide ESD protection.

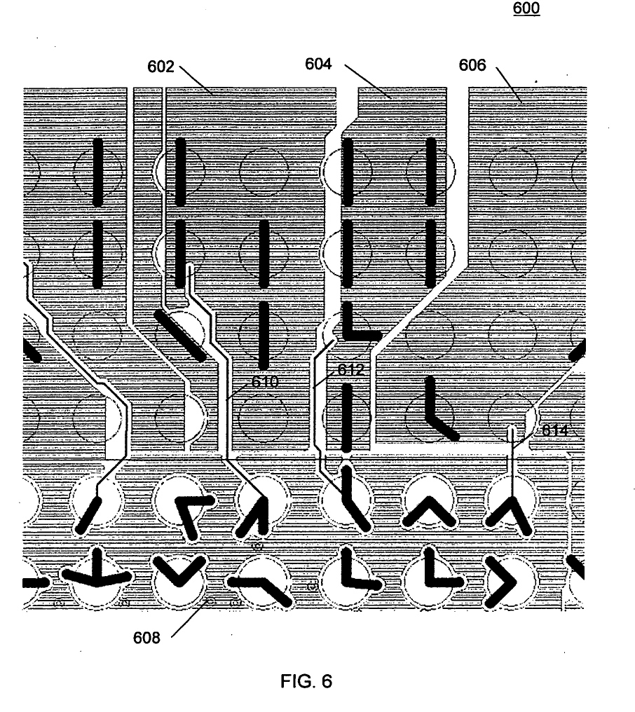

FIG. 6 shows a schematic diagram of a layer 600, according to an embodiment of the present invention. Layer 600 may be a layer of substrate, e.g., similar to substrate 400 as described above. Layer 600 includes analog ground planes 602, 604 and 606, associated with corresponding analog circuits, and a digital ground plane 608, associated with corresponding digital circuits. Analog ground plane 602, 604 and 606 may be separated from each other to maintain separation between their respective analog circuit blocks and other circuit blocks of the substrate. Each of analog ground planes 602, 604 and 606 are also separated from digital ground plane 608. Analog ground planes 602, 604, and 606 are coupled to digital ground plane 608 through traces 610, 612, and 614, respectively. Traces 610, 612, and 614 provide ESD protection when the IC package by allowing ground currents of analog ground planes 602, 604, and 606 and digital ground plane 608 resulting from an ESD event to interact. Furthermore, traces 610, 612, and 614 also do not pass significant currents when the IC package is coupled to a PCB so that isolation is maintained between the circuit blocks coupled to analog ground planes 602, 604, and 606 and digital ground plane 608. This is so because each of analog ground planes 602, 604, and 606 as well as digital ground plane 608 is strongly coupled to a ground plane of the PCB in comparison to the connections between analog ground planes 602, 604, and 606 and digital ground plane 608 through traces 610, 612, and 614. The weak connection through traces 610, 612, and 614 is sufficient to prevent damage from ESD events.

As shown in FIG. 6, traces 610, 614, and 614 couple contact pads coupled to analog ground planes 602, 604 and 606, respectively, to contact pads coupled to digital ground plane 608. Additionally, or alternatively, one or more of analog ground planes 602, 604, and 606 may be coupled to each other through a trace substantially similar to traces 610, 612, or 614.

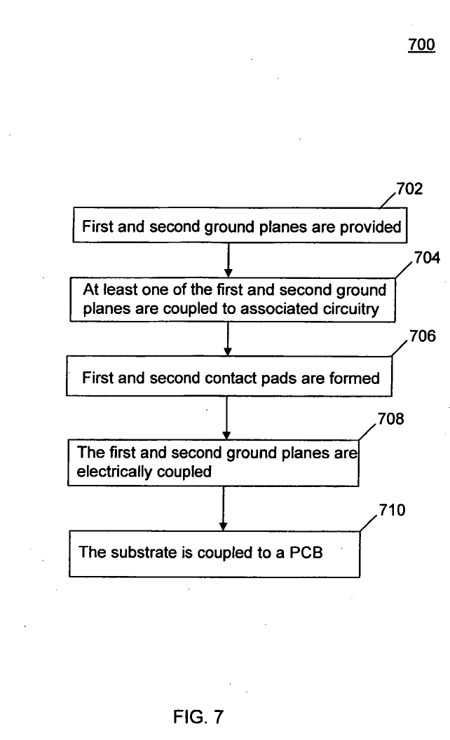

FIG. 7 shows a flowchart 700 providing example steps for forming a substrate. Other structural and operational embodiments will be apparent to persons skilled in the relevant art(s) based on the following discussion. The steps shown in FIG. 7 do not necessarily have to occur in the order shown. The steps of FIG. 7 are described in detail below.

Flowchart 700 begins with step 702. In step 702, first and second ground planes are provided. For example, in FIG. 4, digital and analog ground planes 406 and 408 can provided. As described above, the first and second ground planes may be sections of the same ground plane or occupy different layers of a substrate.

In step 704, at least one of the first and second ground planes are coupled to associated circuitry. For example, digital ground plane 406 can be coupled to output drivers or memory. Additionally or alternatively, analog ground plane 408 may be coupled to one or more signal processing circuits and/or reference frequency sources.

In step 706, first and second contact pads are formed. The first and second contact pads are coupled to the first and second ground planes, respectively. For example, in FIG. 4, contact pads 422 and 424 can be formed. Digital and analog ground planes 406 and 408 may be coupled to contact pads 422 and 424 through vias 418 and 420, respectively.

In step 708, the first and second ground planes are electrically coupled. For example, in FIG. 4, trace 426 can be formed that couples contact pads 422 and 424. Since digital and analog ground planes 406 and 408 are coupled to contact pads 422 and 424, respectively, trace 426 couples digital and analog ground planes 406 and 408. In a further embodiment, the first and second ground planes may be electrically coupled so as to provide ESD protection, as described above.

In optional step 710, the substrate is coupled to a PCB. In an embodiment, the first and second ground planes are strongly coupled to a ground plane of the PCB in comparison to the coupling between the first and second ground planes. In such a manner, the first and second ground planes, or contact pads coupled to the first and second ground planes, are held at substantially identical potentials. Thus, little or no current flows between the first ground plane and the second ground plane and circuit blocks coupled to the first and second ground planes are isolated.

Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A substrate, comprising:
first and second ground planes; and
a trace that couples the first ground plane to the second ground plane;
wherein a signal passed by the first ground plane resulting from an electrostatic discharge (ESD) event interacts with a signal passed by the second ground plane resulting from the ESD event; and wherein the first and second ground planes are substantially isolated when the first and second ground planes are coupled to a ground plane of a printed circuit board (PCB).

2. The substrate of claim 1, further comprising:
first and second contact pads coupled to the first and second ground planes, respectively, wherein the trace couples the first contact pad to the second contact pad.

3. The substrate of claim 1, wherein the trace comprises copper.

4. The substrate of claim 1, wherein the substrate is configured to be included in a ball grid array package, a pin grid array package, or a land grid array package.

5. The substrate of claim 1, wherein the first ground plane is coupled to an analog circuit and the second ground plane is coupled to a digital circuit.

6. The substrate of claim 1, wherein the first ground plane is coupled to a memory.

7. The substrate of claim 1, wherein the first ground plane is coupled is coupled to a signal processing device.

8. The substrate of claim 1, wherein an impedance of the trace is sufficiently low so that ESD protection is provided and sufficiently high so that substantially no current is passed over the trace after the substrate is coupled to the PCB.

9. A method of forming a substrate, comprising:
providing first and second ground planes; and
electrically coupling the first and second ground planes;
wherein a signal passed by the first ground plane resulting from an electrostatic discharge (ESD) event interacts with a signal passed by the second ground plane resulting from the ESD event; and wherein the first and second ground planes are substantially isolated when the first and second ground planes are coupled to a ground plane of a printed circuit board (PCB).

10. The method of claim 9, further comprising:
forming first and second contact pads that are coupled to the first and second ground planes, respectively;
wherein the coupling step comprises:
forming a coupling that couples the first and second contact pads.

11. The method of claim 10, wherein the coupling step comprises:
forming a trace that couples the first and second contact pads.

12. The method of claim 9, further comprising:
coupling the first ground plane to an analog circuit; and
coupling the second ground plane to a digital circuit.

13. The method of claim 9, further comprising:
coupling the first ground plane to a memory.

14. A substrate, comprising:
first and second ground planes; and
means for coupling the first ground plane to the second ground plane so that a signal passed by the first ground plane resulting from an electrostatic discharge (ESD) event interacts with a signal passed by the second ground plane resulting from the ESD event; and wherein the first and second ground planes are substantially isolated when the first and second ground planes are coupled to a ground plane of a printed circuit board (PCB).
